(19) United States
(12) Patent Application Publication
(10) Pub. No.: US 2025/0081548 A1
(43) Pub. Date: Mar. 6, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Hiroki HATADA, Kanazawa Ishikawa (JP); Tsuyoshi KACHI, Kanazawa Ishikawa (JP)

(21) Appl. No.: 18/596,042

(22) Filed: Mar. 5, 2024

(30) Foreign Application Priority Data
Sep. 5, 2023 (JP) 2023-143975

(51) Int. Cl. H01L 29/06; H01L 29/04; H01L 29/423

(52) U.S. Cl. CPC H10D 62/117; H10D 62/405; H10D 64/514

(57) ABSTRACT

A semiconductor device includes first and second electrodes, first to third semiconductor regions, a structure body, and first and second connection parts. The structure body includes an insulating part, and third and fourth electrodes. A shape of the structure body in a plane is a first hexagon. The first hexagon includes a pair of first sides, a pair of second sides, and a pair of third sides. A length of the pair of first sides is greater than a length of the pair of second sides. The fourth electrode includes a pair of first electrode regions, a pair of second electrode regions, and a pair of third electrode regions. The second connection part is located on the pair of first electrode regions.

### CROSS-REFERENCE TO RELATED APPLICATIONS

This application is based upon and claims the benefit of priority from Japanese Patent Application No. 2023-143975, filed on Sep. 5, 2023; the entire contents of which are incorporated herein by reference.

### FIELD

Embodiments described herein relate generally to a semiconductor device.

### BACKGROUND

A semiconductor device such as a MOSFET (Metal Oxide Semiconductor Field Effect Transistor) or the like is used in power conversion and the like. It is desirable to increase the manufacturing yield of the semiconductor device.

### BRIEF DESCRIPTION OF THE DRAWINGS

FIG. 1 is a plan view illustrating a semiconductor device according to a first embodiment;

FIG. 2 is a plan view illustrating a portion of the semiconductor device according to the first embodiment;

FIG. 3 is a cross-sectional view illustrating a portion of the semiconductor device according to the first embodiment;

FIG. 4 is a plan view illustrating a structure body of the semiconductor device according to the first embodiment;

FIG. 5 is a plan view illustrating a structure body of a semiconductor device according to a first modification of the first embodiment;

FIG. 6 is a plan view illustrating a portion of a semiconductor device according to a second modification of the first embodiment;

FIG. 7 is a plan view illustrating a portion of a semiconductor device according to a third modification of the first embodiment;

FIG. 8 is a plan view illustrating a structure body of the semiconductor device according to the third modification of the first embodiment;

FIG. 9 is an enlarged plan view illustrating a portion of a semiconductor device according to a second embodiment; and

FIG. 10 is a plan view illustrating a structure body of the semiconductor device according to the second embodiment.

### DETAILED DESCRIPTION

A semiconductor device according to an embodiment includes a first electrode, a first semiconductor region of a first conductivity type, a second semiconductor region of a second conductivity type, a third semiconductor region of the first conductivity type, a second electrode, a structure body, a first connection part, and a second connection part. The first semiconductor region is located on the first electrode. The second semiconductor region is located on the first semiconductor region. The third semiconductor region is located on the second semiconductor region. The second electrode is located on the third semiconductor region. The second electrode is electrically connected with the third semiconductor region. The structure body includes an insulating part, a third electrode, and a fourth electrode. The insulating part is arranged with the third semiconductor region, the second semiconductor region, and a portion of the first semiconductor region in a second direction and a third direction. The second direction is perpendicular to a first direction; and the first direction is from the first electrode toward the second electrode. The third direction is perpendicular to the first and second directions. The third electrode is arranged with the first semiconductor region in the second and third directions with the insulating part interposed. The fourth electrode surrounds the third electrode in the second and third directions. The fourth electrode is arranged with the second semiconductor region in the second and third directions with the insulating part interposed. The first connection part is located on the third electrode. The first connection part is electrically connected with the third electrode. The second connection part is located on the fourth electrode. The second connection part is electrically connected with the fourth electrode. A shape of the structure body in a plane parallel to the second and third directions is a first hexagon including a pair of first sides, a pair of second sides, and a pair of third sides. The pair of first sides is parallel to each other. The pair of second sides is parallel to each other and crosses the pair of first sides. The pair of third sides is parallel to each other and crosses the pair of first sides and the pair of second sides. A length of the pair of first sides is greater than a length of the pair of second sides. The fourth electrode includes a pair of first electrode regions, a pair of second electrode regions, and a pair of third electrode regions. The pair of first electrode regions is along the pair of first sides. The pair of second electrode regions is along the pair of second sides. The pair of third electrode regions is along the pair of third sides. The second connection part is located on the pair of first electrode regions.

A semiconductor device according to an embodiment includes a first electrode, a first semiconductor region of a first conductivity type, a second semiconductor region of a second conductivity type, a third semiconductor region of the first conductivity type, a second electrode, a structure body, a first connection part, and a second connection part. The first semiconductor region is located on the first electrode. The second semiconductor region is located on the first semiconductor region. The third semiconductor region is located on the second semiconductor region. The second electrode is located on the third semiconductor region. The second electrode is electrically connected with the third semiconductor region. The structure body includes an insulating part, a third electrode, and a fourth electrode. The insulating part is arranged with the third semiconductor region, the second semiconductor region, and a portion of the first semiconductor region in a second direction and a third direction. The second direction is perpendicular to a first direction; and the first direction is from the first electrode toward the second electrode. The third direction is perpendicular to the first and second directions. The third electrode is arranged with the first semiconductor region in the second and third directions with the insulating part interposed. The fourth electrode surrounds the third electrode in the second and third directions. The fourth electrode is arranged with the second semiconductor region in the second and third directions with the insulating part interposed. The first connection part is located on the third electrode. The first connection part is electrically connected with the third electrode. The second connection part is located on the fourth electrode. The second connection part is electrically connected with the fourth electrode. A shape of the structure body in a plane parallel to the second and third directions is a first oval including a pair of first sides and a pair of first arcs. The pair of first sides is parallel to each other. The pair of first arcs connects the pair of first sides to each other. The fourth electrode includes a pair of first electrode regions and a pair of second electrode regions. The pair of first electrode regions is along the pair of first sides. The pair of second electrode regions is along the pair of first arcs. The second connection part is located on the pair of first electrode regions.

Embodiments of the invention will now be described with reference to the drawings.

The drawings are schematic or conceptual; and the relationships between the thickness and width of portions, the proportions of sizes among portions, etc., are not necessarily the same as the actual values. The dimensions and proportions may be illustrated differently among drawings, even when the same portion is illustrated.

In the specification and drawings, components similar to those already described are marked with the same reference numerals; and a detailed description is omitted as appropriate.

In the following description and drawings, the notations of n⁺, n⁻, p⁺, and p indicate relative levels of the impurity concentrations. Namely, a notation marked with “+” indicates that the impurity concentration is relatively greater than that of a notation not marked with either “+” or “−”; and a notation marked with “−” indicates that the impurity concentration is relatively less than that of an unmarked notation. When both a p-type impurity and an n-type impurity are included in each region, these notations indicate relative levels of the net impurity concentrations after the impurities compensate each other.

In the embodiments described below, each embodiment may be implemented by inverting the p-type and the n-type of the semiconductor regions.

### First Embodiment

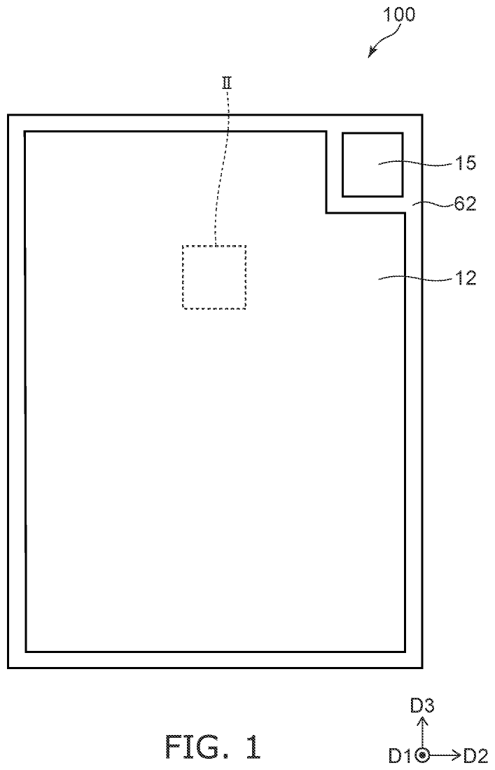

FIG. 1 is a plan view illustrating a semiconductor device according to a first embodiment.

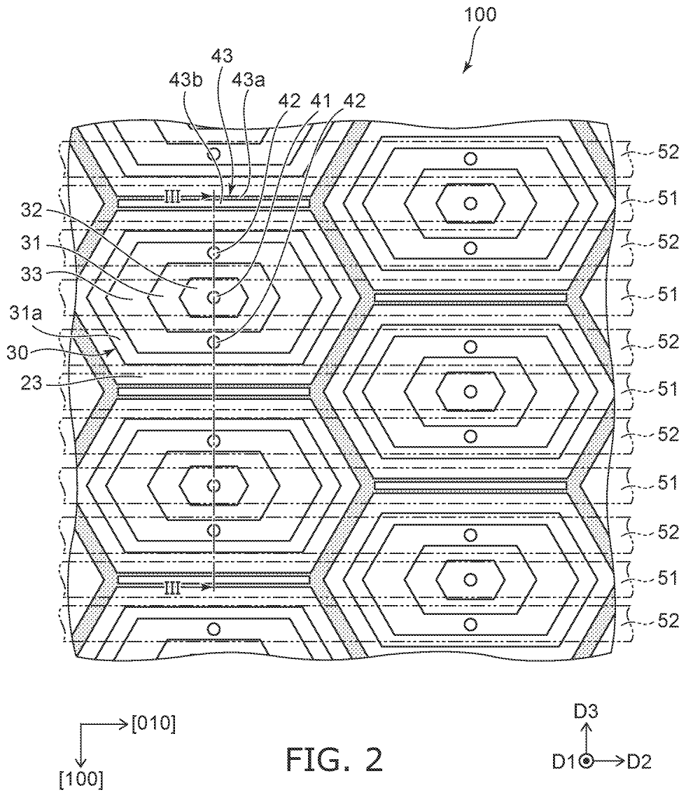

FIG. 2 is a plan view illustrating a portion of the semiconductor device according to the first embodiment.

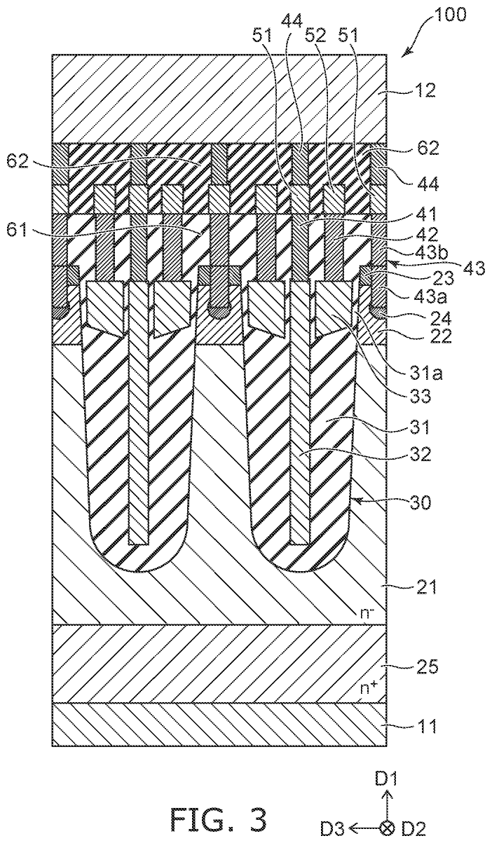

FIG. 3 is a cross-sectional view illustrating a portion of the semiconductor device according to the first embodiment.

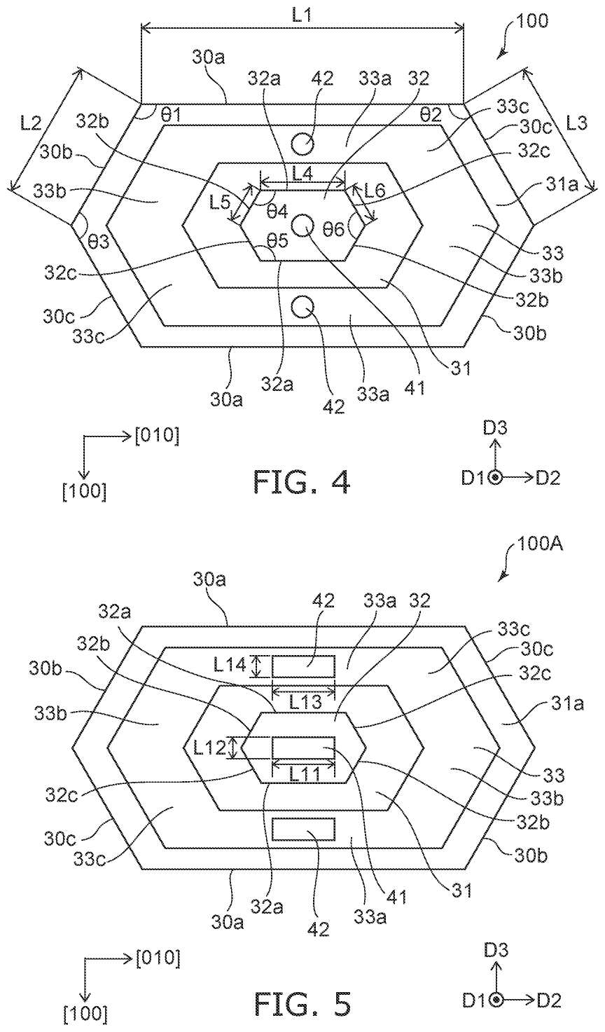

FIG. 4 is a plan view illustrating a structure body of the semiconductor device according to the first embodiment. FIG. 2 illustrates region II shown in FIG. 1.

FIG. 3 is a cross-sectional view along line III-III shown in FIG. 2.

The semiconductor device 100 according to the first embodiment is a vertical MOSFET. The semiconductor device 100 is a MOSFET having a so-called dot structure.

As illustrated in FIGS. 1 to 3, the semiconductor device 100 includes a drain electrode 11 (a first electrode), a source electrode 12 (a second electrode), a gate pad 15, an n⁻-type drift region 21 (a first semiconductor region), a p-type base region 22 (a second semiconductor region), an n⁺-type source region 23 (a third semiconductor region), a p⁺-type contact region 24, an n⁺-type drain region 25, a structure body 30, a first connection part 41 (first connector, first source contact), a second connection part 42 (second connector, gate contact), a third connection part 43 (third connector, third source contact), a fourth connection part 44 (fourth connector, second source contact), a source interconnect layer 51, a gate wiring layer 52, a first insulating layer 61, and a second insulating layer 62. In the semiconductor device 100, the first conductivity type is an n-type; and the second conductivity type is a p-type. In FIG. 2, the source electrode 12, the fourth connection part 44, the first insulating layer 61, and the second insulating layer 62 are not illustrated, and the source interconnect layer 51 and the gate wiring layer 52 are illustrated by double dot-dash lines.

A first direction D1, a second direction D2, and a third direction D3 are used in the description of the following embodiments. The direction from the drain electrode 11 toward the source electrode 12 is taken as the first direction D1. One direction perpendicular to the first direction D1 is taken as the second direction D2. A direction perpendicular to the first and second directions D1 and D2 is taken as the third direction D3. Although the direction from the drain electrode 11 toward the source electrode 12 is taken as “up/upward/higher than”, and the opposite direction is taken as “down/downward/lower than” for easier understanding of the description, these directions are independent of the direction of gravity.

As illustrated in FIG. 1, the source electrode 12 and the gate pad 15 are located at the upper surface of the semiconductor device 100. The source electrode 12 and the gate pad 15 are electrically isolated from each other.

As illustrated in FIG. 3, the drain electrode 11 is located at the lower surface of the semiconductor device 100. The n⁻-type drift region 21 is located on the drain electrode 11 with the n⁺-type drain region 25 interposed. The n⁻-type drift region 21 is electrically connected with the drain electrode 11 via the n⁺-type drain region 25. The p-type base region 22 is located on the n⁻-type drift region 21. The n⁺-type source region 23 and the p⁺-type contact region 24 are located on the p-type base region 22. The p⁺-type contact region 24 is positioned lower than the n⁺-type source region 23.

The structure body 30 includes an insulating part 31, a FP electrode 32 (a third electrode), and a gate electrode 33 (a fourth electrode). The insulating part 31 is arranged with the n⁺-type source region 23, the p-type base region 22, and a portion of the n⁻-type drift region 21 in the second and third directions D2 and D3.

The FP electrode 32 is located inside the insulating part 31. A portion of the FP electrode 32 is arranged with a portion of the n⁻-type drift region 21 in the second and third directions D2 and D3 with the insulating part 31 interposed. Another portion of the FP electrode 32 is arranged with the p-type base region 22 in the second and third directions D2 and D3 with the insulating part 31 interposed.

The gate electrode 33 is located inside the insulating part 31. The gate electrode 33 is located around the upper portion of the FP electrode 32 along the second and third directions D2 and D3. The gate electrode 33 surrounds the FP electrode 32 in the second and third directions D2 and D3. A portion of the insulating part 31 is located between the FP electrode 32 and the gate electrode 33. As a result, the FP electrode 32 and the gate electrode 33 are electrically isolated from each other.

At least a portion of the gate electrode 33 is arranged with the p-type base region 22 in the second and third directions D2 and D3 with a gate insulating layer 31a interposed. In the semiconductor device 100, another portion of the gate electrode 33 is arranged with the n⁻-type drift region 21 and the n⁺-type source region 22 with the gate insulating layer 31a interposed. In the semiconductor device 100, a portion of the insulating part 31 functions as the gate insulating layer 31a.

As illustrated in FIG. 2, multiple structure bodies 20 are arranged along a plane along the second and third directions D2 and D3. For example, one continuous p-type base region 22 is located around the multiple gate electrodes 33. The multiple n⁺-type source regions 23 are located respectively around the multiple gate electrodes 33.

As illustrated in FIG. 3, the first insulating layer 61 is located on the p-type base region 22, the multiple n⁺-type source regions 23, the multiple gate electrodes 33, and the multiple structure bodies 20. The source interconnect layer 51 and the gate wiring layer 52 are located on the first insulating layer 61. The second insulating layer 62 is located on the source interconnect layer 51, the gate wiring layer 52, and the first insulating layer 61. The source electrode 12 and the gate pad 15 are located on the second insulating layer 62.

The source electrode 12 is positioned on the p-type base region 22, the multiple n⁺-type source regions 23, the multiple gate electrodes 33, and the multiple structure bodies 20.

A portion of the source interconnect layer 51 is located between the FP electrode 32 and the source electrode 12 in the first direction D1. The first connection part 41 is located between the FP electrode 32 and the source interconnect layer 51 in the first direction D1. The fourth connection part 44 is located between the source interconnect layer 51 and the source electrode 12 in the first direction D1. The FP electrode 32 is electrically connected with the source electrode 12 via the first connection part 41, the source interconnect layer 51, and the fourth connection part 44.

Another portion of the source interconnect layer 51 is located between the p⁺-type contact region 24 and the source electrode 12 in the first direction D1. The third connection part 43 is located between the p⁺-type contact region 24 and the source interconnect layer 51 in the first direction D1. The p⁺-type contact region 24 is electrically connected with the source electrode 12 via the third connection part 43, the source interconnect layer 51, and the fourth connection part 44. Similarly, the p-type base region 22 is electrically connected with the source electrode 12 via the third connection part 43, the source interconnect layer 51, and the fourth connection part 44. Similarly, the n⁺-type source region 23 is electrically connected with the source electrode 12 via the third connection part 43, the source interconnect layer 51, and the fourth connection part 44.

The third connection part 43 includes a first connection region 43a and a second connection region 43b. The first connection region 43a surrounds the structure body 20 in the second and third directions D2 and D3. The first connection region 43a is located between the n⁺-type source regions 23. The first connection region 43a contacts the p-type base region 22, the n⁺-type source region 23, and the p⁺-type contact region 24. The second connection region 43b extends upward from the first connection region 43a and is electrically connected with the source interconnect layer 51.

The gate wiring layer 52 is located between the gate electrode 33 and the source electrode 12 in the first direction D1. The third connection part 43 is located between the gate electrode 33 and the gate wiring layer 52 in the first direction D1. The gate electrode 33 is electrically connected with the gate wiring layer 52 via the second connection part 42. The gate wiring layer 52 is electrically connected with the gate pad 15.

In the semiconductor device 100, the source interconnect layer 51 and the gate wiring layer 52 extend along the second direction D2. The source interconnect layer 51 and the gate wiring layer 52 may extend along a direction crossing the second direction D2.

In the semiconductor device 100 as illustrated in FIG. 4, the shape of the structure body 30 in a plane parallel to the second and third directions D2 and D3 is a first hexagon including a pair of first sides 30a, a pair of second sides 30b, and a pair of third sides 30c. The pair of first sides 30a is parallel to each other. The pair of second sides 30b is parallel to each other and crosses the pair of first sides 30a. The pair of third sides 30c is parallel to each other and crosses the pair of first sides 30a and the pair of second sides 30b. In the semiconductor device 100, the pair of first sides 30a extends along the second direction D2. The pair of second sides 30b and the pair of third sides 30c extend along directions oblique to the second direction D2.

A length L1 of the pair of first sides 30a is greater than a length L2 of the pair of second sides 30b. In the semiconductor device 100, the length L1 of the pair of first sides 30a is greater than a length L3 of the pair of third sides 30c. The length L2 of the pair of second sides 30b is equal to the length L3 of the pair of third sides 30c. In the semiconductor device 100, an angle θ1 between the pair of first sides 30a and the pair of second sides 30b, an angle θ2 between the pair of first sides 30a and the pair of third sides 30c, and an angle θ3 between the pair of second sides 30b and the pair of third sides 30c each are 120°. In the semiconductor device 100, the shape of the structure body 30 in the plane parallel to the second and third directions D2 and D3 is a regular hexagon elongated in the direction (the second direction D2) in which the pair of first sides 30a extends.

In the semiconductor device 100, the shape of the FP electrode 32 in the plane parallel to the second and third directions D2 and D3 is a second hexagon including a pair of fourth sides 32a, a pair of fifth sides 32b, and a pair of sixth sides 32c. The pair of fourth sides 32a is parallel to each other and is along the pair of first sides 30a. The pair of fifth sides 32b is parallel to each other and is along the pair of second sides 30b. The pair of sixth sides 32c is parallel to each other and is along the pair of third sides 30c. In the semiconductor device 100, the pair of fourth sides 32a extends along the second direction D2. The pair of fifth sides 32b and the pair of sixth sides 32c extend along directions oblique to the second direction D2.

A length L4 of the pair of fourth sides 32a is greater than a length L5 of the pair of fifth sides 32b. In the semiconductor device 100, the length L4 of the pair of fourth sides 32a is greater than a length L6 of the pair of sixth sides 32c. The length L5 of the pair of fifth sides 32b is equal to the length L6 of the pair of sixth sides 32c. In the semiconductor device 100, an angle θ4 between the pair of fourth sides 32a and the pair of fifth sides 32b, an angle θ5 between the pair of fourth sides 32a and the pair of sixth sides 32c, and an angle θ6 between the pair of fifth sides 32b and the pair of sixth sides 32c each are 120°. In the semiconductor device 100, the shape of the FP electrode 32 in the plane parallel to the second and third directions D2 and D3 is a regular hexagon elongated in the direction (the second direction D2) in which the pair of fourth sides 32a extends.

In the semiconductor device 100, the gate electrode 33 includes a pair of first electrode regions 33a, a pair of second electrode regions 33b, and a pair of third electrode regions 33c. The pair of first electrode regions 33a is along the pair of first sides 30a. The pair of second electrode regions 33b is along the pair of second sides 30b. The pair of third electrode regions 33c is along the pair of third sides 30c. In the semiconductor device 100, the pair of first electrode regions 33a extends along the second direction D2. The pair of second electrode regions 33b and the pair of third electrode regions 33c extend along directions oblique to the second direction D2.

The second connection part 42 is located on the pair of first electrode regions 33a of the gate electrode 33. In the semiconductor device 100, two second connection parts 42 are located at one structure body 30 (gate electrode 33). One of the second connection parts 42 is located on one of the pair of first electrode regions 33a; and the other second connection part 42 is located on the other of the pair of first electrode regions 33a.

The first connection part 41 is located on the FP electrode 32. In the semiconductor device 100, the first connection part 41 is located between two second connection parts 42. In the semiconductor device 100, the direction in which the first connection part 41 and the two second connection parts 42 are arranged is along the third direction D3.

In the semiconductor device 100, the shapes of the first and second connection parts 41 and 42 in the plane parallel to the second and third directions D2 and D3 are circles. The shapes of the first and second connection parts 41 and 42 in the plane parallel to the second and third directions D2 and D3 may be, for example, polygons such as rectangles, etc., described below.

In the semiconductor device 100, the pair of first sides 30a is along a (100) plane of the crystal of the silicon included in the n⁻-type drift region 21.

Operations of the semiconductor device 100 will now be described.

A voltage that is not less than a threshold is applied to the gate electrode 33 in a state in which a positive voltage with respect to the source electrode 12 is applied to the drain electrode 11. As a result, a channel (an inversion layer) is formed in the p-type base region 22; and the semiconductor device 100 is set to an on-state. Electrons flow from the source electrode 12 toward the drain electrode 11 via the channel. Subsequently, when the voltage applied to the gate electrode 33 drops below the threshold, the channel in the p-type base region 22 disappears, and the semiconductor device 100 is set to an off-state.

When the semiconductor device 100 is switched to the off-state, the positive voltage with respect to the source electrode 12 that is applied to the drain electrode 11 increases. In other words, the potential difference between the n⁻-type drift region 21 and the FP electrode 32 increases. The increase of the potential difference causes a depletion layer to spread from the interface between the insulating part 31 and the n⁻-type drift region 21 toward the n⁻-type drift region 21. The spreading of the depletion layer can increase the breakdown voltage of the semiconductor device 100. Or, the concentration of the impurity that forms donors in the n⁻-type drift region 21 can be increased and the on-resistance of the semiconductor device 100 can be reduced while maintaining the breakdown voltage of the semiconductor device 100.

Examples of the materials of the components of the semiconductor device 100 will now be described.

The drain electrode 11, the source electrode 12, and the gate pad 15 include metals such as aluminum, copper, etc.

The n⁻-type drift region 21, the p-type base region 22, the n⁺-type source region 23, the p⁺-type contact region 24, and the n⁺-type drain region 25 include silicon, silicon carbide, gallium nitride, or gallium arsenide as a semiconductor material. When silicon is used as the semiconductor material, arsenic, phosphorus, or antimony can be used as an impurity that forms donors. Boron can be used as an impurity that forms acceptors.

The FP electrode 32 and the gate electrode 33 include conductive materials such as polysilicon, etc. Impurities may be added to the conductive materials.

The insulating part 31, the first insulating layer 61, and the second insulating layer 62 include insulating materials. The insulating part 31, the first insulating layer 61, and the second insulating layer 62 include, for example, silicon oxide or silicon nitride.

The first connection part 41, the second connection part 42, the third connection part 43, the fourth connection part 44, the source interconnect layer 51, and the gate wiring layer 52 include metals such as tungsten, aluminum, copper, etc.

Effects of the first embodiment will now be described.

In the semiconductor device 100, multiple FP electrodes 32 are arranged in the second and third directions D2 and D3. According to this structure, compared to when the FP electrode 32 extends continuously in one direction, the volume of the n⁻-type drift region 21 used as the current path can be increased. The on-resistance of the semiconductor device 100 can be reduced thereby. In the semiconductor device 100, multiple gate electrodes 33 also are arranged in the second and third directions D2 and D3. According to this structure, compared to when the gate electrode 33 is extended continuously in one direction, channels are formed in more regions. The channel density is increased, and the on-resistance of the semiconductor device 100 is further reduced. For example, when the on-resistance of the semiconductor device 100 is reduced, the current density flowing through the semiconductor device 100 can be increased. By increasing the current density, the semiconductor device 100 can be smaller. Or, the number of the semiconductor devices 100 necessary to carry the prescribed current can be reduced.

On the other hand, when multiple gate electrodes 33 are arranged in the second and third directions D2 and D3, the second connection parts 42 are provided respectively for the gate electrodes 33. To increase the yield by more reliably locating the second connection parts 42 on the gate electrodes 33, it is desirable to increase the misalignment margin when forming the second connection parts 42.

In the semiconductor device 100 as illustrated in FIG. 4, the shape of the structure body 30 in the plane parallel to the second and third directions D2 and D3 is a regular hexagon elongated in a direction (the second direction D2) along the pair of first sides 30a; and the second connection parts 42 are located on the pair of first electrode regions 33a along the pair of first sides 30a. By locating the second connection parts 42 on the pair of first electrode regions 33a that is longer than the other regions, the misalignment margin when forming the second connection parts 42 can be greater than when the shape of the structure body 30 in the plane parallel to the second and third directions D2 and D3 is a regular hexagon. Accordingly, the manufacturing yield of the semiconductor device 100 can be increased.

Similarly, when multiple FP electrodes 32 are arranged in the second and third directions D2 and D3, the first connection parts 41 are provided respectively for the FP electrodes 32. To increase the yield of locating the first connection parts 41 more reliably on the FP electrodes 32, it is desirable to increase the misalignment margin when forming the first connection parts 41.

In the semiconductor device 100 as illustrated in FIG. 4, the shape of the FP electrode 32 in the plane parallel to the second and third directions D2 and D3 is a regular hexagon elongated in a direction (the second direction D2) along the pair of fourth sides 32a. By shaping such a shape of the FP electrode 32 in the plane parallel to the second and third directions D2 and D3, the misalignment margin when forming the first connection parts 41 can be greater than when the shape of the FP electrode 32 in the plane parallel to the second and third directions D2 and D3 is a regular hexagon. Accordingly, the manufacturing yield of the semiconductor device 100 can be increased.

When the n⁻-type drift region 21 includes silicon, each plane orientation of the silicon crystal tends to have a different channel mobility. Specifically, the channel mobility in the (100) plane of the silicon crystal tends to be greater than the channel mobility in planes oblique to the (100) plane. Also, when the n⁻-type drift region 21 includes silicon, each plane orientation of the silicon crystal tends to have a different silicon oxidation rate. Specifically, the oxidation rate in the (100) plane of the silicon crystal tends to be slower than the oxidation rate in planes oblique to the (100) plane. Therefore, the thickness of the insulating part 31 at surfaces along the (100) plane tends to be less than the thickness of the insulating part 31 at surfaces oblique to the (100) plane. As a result, when the n⁻-type drift region 21 includes silicon, the channel resistance in the (100) plane of the silicon crystal tends to be less than the channel resistance in planes oblique to the (100) plane.

In the semiconductor device 100, the pair of first sides 30a is along the (100) plane of the silicon crystal included in the n⁻-type drift region 21. As a result, the (100) plane that has a low channel resistance can be set to be longer than the other planes. Accordingly, the on-resistance of the semiconductor device 100 can be less than when the pair of first sides 30a is oblique to the (100) plane.

### First Modification

FIG. 5 is a plan view illustrating a structure body of a semiconductor device according to a first modification of the first embodiment.

In the semiconductor device 100A according to the first modification of the first embodiment as illustrated in FIG. 5, the shapes of the first and second connection parts 41 and 42 in the plane parallel to the second and third directions D2 and D3 are different from those of the semiconductor device 100. Otherwise, the semiconductor device 100A is the same as the semiconductor device 100.

In the semiconductor device 100A, the shapes of the first and second connection parts 41 and 42 in the plane parallel to the second and third directions D2 and D3 are rectangles. The pair of first sides 30a is along the second direction D2. A length L11 in the second direction D2 of the first connection part 41 is greater than a length L12 in the third direction D3 of the first connection part 41. For example, the length L11 is greater than 2 times the length L12. A length L13 in the second direction D2 of the second connection part 42 is greater than a length L14 in the third direction D3 of the second connection part 42. For example, the length L13 is greater than 2 times the length L14.

By setting the length L11 in the second direction D2 of the first connection part 41 to be greater than the length L12 in the third direction D3 of the first connection part 41, compared to when the length L11 and the length L12 are equal, formation defects when forming the first connection part 41 can be suppressed. The manufacturing yield of the semiconductor device 100 can be increased thereby.

By setting the length L13 in the second direction D2 of the second connection part 42 to be greater than the length L14 in the third direction D3 of the second connection part 42, compared to when the length L13 and the length L14 are equal, the formation defects when forming the second connection part 42 can be suppressed. The manufacturing yield of the semiconductor device 100 can be increased thereby.

### Second Modification

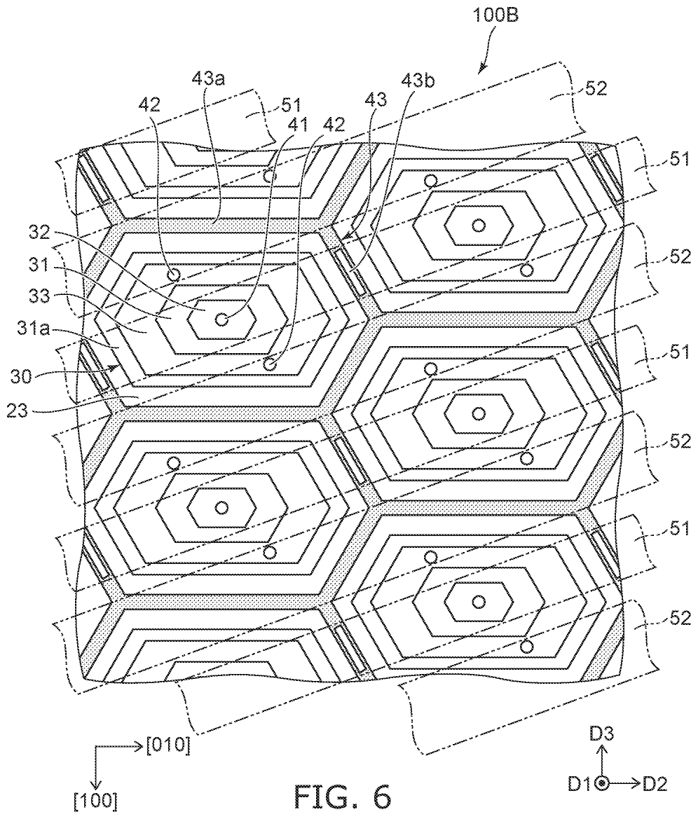

FIG. 6 is a plan view illustrating a portion of a semiconductor device according to a second modification of the first embodiment.

FIG. 6 illustrates a region corresponding to region II shown in FIG. 1.

In the semiconductor device 100B according to the second modification of the first embodiment as illustrated in FIG. 6, the arrangement of the first and second connection parts 41 and 42 is different from that of the semiconductor device 100. Also, the arrangement of the source interconnect layer 51 and the gate wiring layer 52 of the semiconductor device 100B is different from that of the semiconductor device 100. Otherwise, the semiconductor device 100B is the same as the semiconductor device 100.

In the semiconductor device 100B, the direction in which the first connection part 41 and the two second connection parts 42 are arranged crosses the second and third directions D2 and D3. In the semiconductor device 100B, the source interconnect layer 51 and the gate wiring layer 52 extend along a direction crossing the second and third directions D2 and D3.

### Third Modification

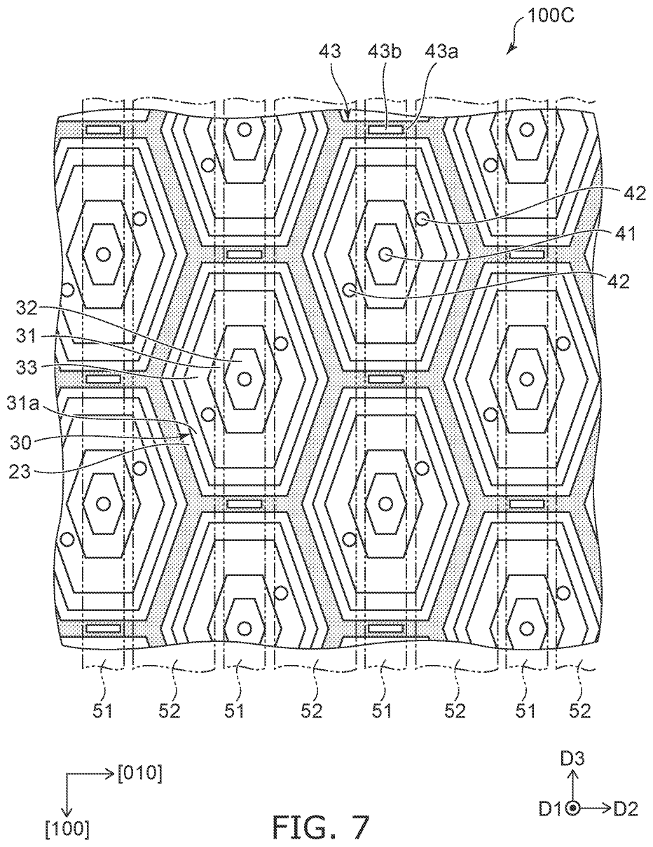

FIG. 7 is a plan view illustrating a portion of a semiconductor device according to a third modification of the first embodiment.

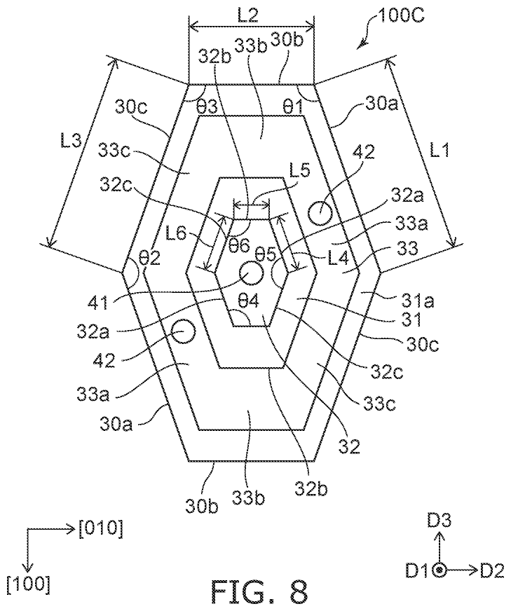

FIG. 8 is a plan view illustrating a structure body of the semiconductor device according to the third modification of the first embodiment.

FIG. 7 illustrates a region corresponding to region II shown in FIG. 1.

In the semiconductor device 100C according to the third modification of the first embodiment as illustrated in FIGS. 7 and 8, the shape of the structure body 30 in the plane parallel to the second and third directions D2 and D3 is different from that of the semiconductor device 100. Otherwise, the semiconductor device 100C is the same as the semiconductor device 100.

In the semiconductor device 100C, the shape of the structure body 30 in the plane parallel to the second and third directions D2 and D3 is a first hexagon including the pair of first sides 30a, the pair of second sides 30b, and the pair of third sides 30c. In the semiconductor device 100C, the pair of second sides 30b of the structure body 30 extends along the second direction D2. The pair of first sides 30a and the pair of third sides 30c extend along directions oblique to the second direction D2.

The length L1 of the pair of first sides 30a is greater than the length L2 of the pair of second sides 30b. In the semiconductor device 100C, the length L3 of the pair of third sides 30c is equal to the length L1 of the pair of first sides 30a. In the semiconductor device 100, the angle θ1 between the pair of first sides 30a and the pair of second sides 30b and the angle θ3 between the pair of second sides 30b and the pair of third sides 30c each are less than 120°. The angle θ2 between the pair of first sides 30a and the pair of third sides 30c is greater than 120°. In the semiconductor device 100C, the shape of the structure body 30 in the plane parallel to the second and third directions D2 and D3 is a regular hexagon elongated in a direction (the third direction D3) perpendicular to the direction (the second direction D2) in which the pair of second sides 30b extends.

In the semiconductor device 100C, the pair of fifth sides 32b of the FP electrode 32 extends along the second direction D2. The pair of fourth sides 32a and the pair of sixth sides 32c extend along directions oblique to the second direction D2.

The length L4 of the pair of fourth sides 32a is greater than the length L5 of the pair of fifth sides 32b. In the semiconductor device 100, the length L6 of the pair of sixth sides 32c is equal to the length L4 of the pair of fourth sides 32a. In the semiconductor device 100C, the angle θ4 between the pair of fourth sides 32a and the pair of fifth sides 32b and the angle θ6 between the pair of fifth sides 32b and the pair of sixth sides 32c each are less than 120°. The angle θ5 between the pair of fourth sides 32a and the pair of sixth sides 32c is greater than 120°. In the semiconductor device 100C, the shape of the FP electrode 32 in the plane parallel to the second and third directions D2 and D3 is a regular hexagon elongated in a direction (the third direction D3) perpendicular to the direction (the second direction D2) in which the pair of fifth sides 32b extends.

In the semiconductor device 100C, the pair of second electrode regions 33b of the gate electrode 33 extends along the second direction D2. The pair of first electrode regions 33a and the pair of third electrode regions 33c extend along directions oblique to the second direction D2.

The second connection part 42 is located on the pair of first electrode regions 33a of the gate electrode 33. In the semiconductor device 100C, two second connection parts 42 are provided for one structure body 30 (gate electrode 33). One of the second connection parts 42 is located on one of the pair of first electrode regions 33a; and the other of the second connection parts 42 is located on the other of the pair of first electrode regions 33a.

The first connection part 41 is located on the FP electrode 32. In the semiconductor device 100C, the first connection part 41 is located between the two second connection parts 42. In the semiconductor device 100C, the direction in which the first connection part 41 and the two second connection parts 42 are arranged crosses the second and third directions D2 and D3. The direction in which the first connection part 41 and the two second connection parts 42 are arranged may be along the second direction D2.

In the semiconductor device 100C, the pair of first sides 30a is not along the (100) plane of the silicon crystal included in the n⁻-type drift region 21.

### Second Embodiment

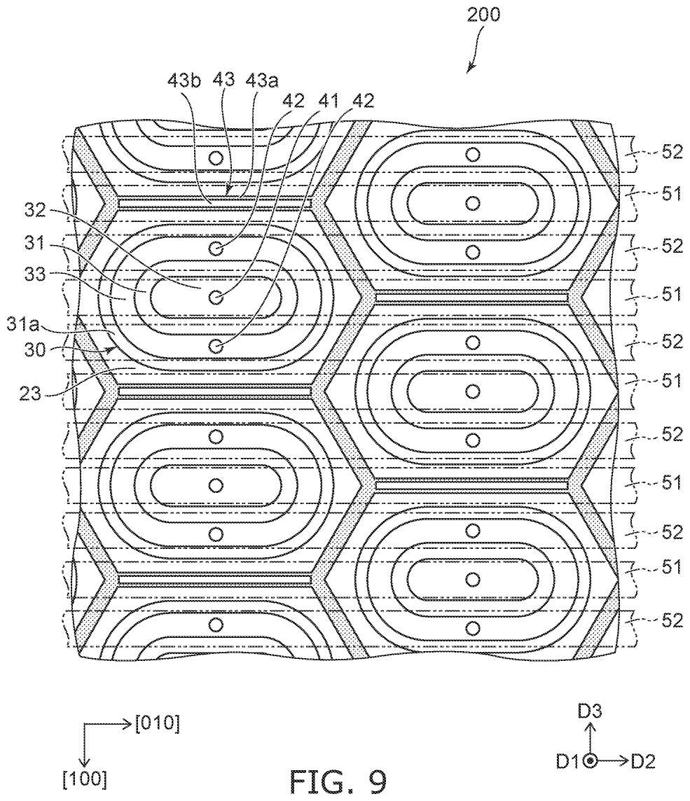

FIG. 9 is an enlarged plan view illustrating a portion of a semiconductor device according to a second embodiment.

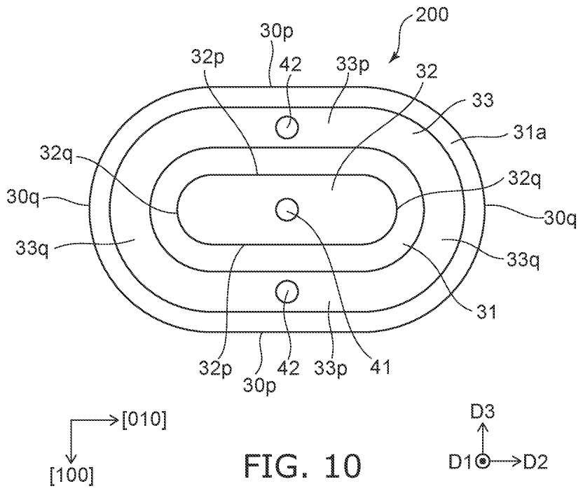

FIG. 10 is a plan view illustrating a structure body of the semiconductor device according to the second embodiment.

FIG. 9 illustrates a region corresponding to region II shown in FIG. 1.

In the semiconductor device 200 according to the second embodiment as illustrated in FIG. 9, the shape of the structure body 30 in the plane parallel to the second and third directions D2 and D3 is different from that of the semiconductor device 100. Otherwise, the semiconductor device 200 is the same as the semiconductor device 100.

In the semiconductor device 200, the shape of the structure body 30 in the plane parallel to the second and third directions D2 and D3 is a first oval including a pair of first sides 30p and a pair of first arcs 30q. The pair of first sides 30p is parallel to each other. The pair of first arcs 30q connects the pair of first sides 30p to each other. In the semiconductor device 200, the pair of first sides 30p extends along the second direction D2. In the semiconductor device 200, the shape of the structure body 30 in the plane parallel to the second and third directions D2 and D3 is a perfect circle elongated in the direction (the second direction D2) in which the pair of first sides 30p extends.

In the semiconductor device 200, the shape of the FP electrode 32 in the plane parallel to the second and third directions D2 and D3 is a second oval including a pair of second sides 32p and a pair of second arcs 32q. The pair of second sides 32p is parallel to each other and is along the pair of first sides 30a. The pair of second arcs 32q connects the pair of second sides 32p to each other. In the semiconductor device 200, the pair of second sides 32p extends along the second direction D2. In the semiconductor device 200, the shape of the FP electrode 32 in the plane parallel to the second and third directions D2 and D3 is a perfect circle elongated in the direction (the second direction D2) in which the pair of second sides 32p extends.

In the semiconductor device 200, the gate electrode 33 includes a pair of first electrode regions 33p and a pair of second electrode regions 33q. The pair of first electrode regions 33a is along the pair of first sides 30p. The pair of second electrode regions 33b is along the pair of first arcs 30q. In the semiconductor device 200, the pair of first electrode regions 33a extends along the second direction D2.

The second connection part 42 is located on the pair of first electrode regions 33p of the gate electrode 33. In the semiconductor device 100, two second connection parts 42 are provided for one structure body 30 (gate electrode 33). One of the second connection parts 42 is located on one of the pair of first electrode regions 33p; and the other of the second connection parts 42 is located on the other of the pair of first electrode regions 33p.

The first connection part 41 is located on the FP electrode 32. In the semiconductor device 200, the first connection part 41 is located between the two second connection parts 42. In the semiconductor device 200, the direction in which the first connection part 41 and the two second connection parts 42 are arranged is along the third direction D3.

In the semiconductor device 200, the shapes of the first and second connection parts 41 and 42 in the plane parallel to the second and third directions D2 and D3 are circles. The shapes of the first and second connection parts 41 and 42 in the plane parallel to the second and third directions D2 and D3 may be, for example, polygons such as the rectangles described above, etc.

In the semiconductor device 200, the pair of first sides 30p is along the (100) plane of the silicon crystal included in the n⁻-type drift region 21.

In the semiconductor device 200 as illustrated in FIG. 10, the shape of the structure body 30 in the plane parallel to the second and third directions D2 and D3 is a perfect circle elongated in the direction (the second direction D2) along the pair of first sides 30p; and the second connection parts 42 are located on the pair of first electrode regions 33p along the pair of first sides 30p. By locating the second connection parts 42 on the pair of first electrode regions 33p, the misalignment margin when forming the second connection parts 42 can be greater than when the shape of the structure body 30 in the plane parallel to the second and third directions D2 and D3 is a perfect circle. Accordingly, the manufacturing yield of the semiconductor device 100 can be increased.

In the semiconductor device 200 as illustrated in FIG. 10, the shape of the FP electrode 32 in the plane parallel to the second and third directions D2 and D3 is a perfect circle elongated in the direction (the second direction D2) along the pair of second sides 32p. By setting the shape of the FP electrode 32 in the plane parallel to the second and third directions D2 and D3 to be such a shape, the misalignment margin when forming the first connection part 41 can be greater than when the shape of the FP electrode 32 in the plane parallel to the second and third directions D2 and D3 is a perfect circle. Accordingly, the manufacturing yield of the semiconductor device 100 can be increased.

In the semiconductor device 200, the pair of first sides 30p is along the (100) plane of the silicon crystal included in the n⁻-type drift region 21. The (100) plane that has a low channel resistance can be lengthened thereby. Accordingly, the on-resistance of the semiconductor device 100 can be less than when the pair of first sides 30a is oblique to the (100) plane.

Embodiments may include the following configurations.

### Configuration 1

A semiconductor device, comprising:
a first electrode;
a first semiconductor region located on the first electrode, the first semiconductor region being of a first conductivity type;
a second semiconductor region located on the first semiconductor region, the second semiconductor region being of a second conductivity type;
a third semiconductor region located on the second semiconductor region, the third semiconductor region being of the first conductivity type;
a second electrode located on the third semiconductor region, the second electrode being electrically connected with the third semiconductor region;
a structure body including
   an insulating part arranged with the third semiconductor region, the second semiconductor region, and a portion of the first semiconductor region in a second direction and a third direction, the second direction being perpendicular to a first direction, the first direction being from the first electrode toward the second electrode, the third direction being perpendicular to the first and second directions,
   a third electrode arranged with the first semiconductor region in the second and third directions with the insulating part interposed, and
   a fourth electrode surrounding the third electrode in the second and third directions, the fourth electrode being arranged with the second semiconductor region in the second and third directions with the insulating part interposed,
a first connection part located on the third electrode, the first connection part being electrically connected with the third electrode; and
a second connection part located on the fourth electrode, the second connection part being electrically connected with the fourth electrode,
a shape of the structure body in a plane parallel to the second and third directions being a first hexagon,
the first hexagon including
   a pair of first sides parallel to each other,
   a pair of second sides parallel to each other, the pair of second sides crossing the pair of first sides, and
   a pair of third sides parallel to each other, the pair of third sides crossing the pair of first sides and the pair of second sides,
a length of the pair of first sides being greater than a length of the pair of second sides,
the fourth electrode including
   a pair of first electrode regions along the pair of first sides,
   a pair of second electrode regions along the pair of second sides, and
   a pair of third electrode regions along the pair of third sides,
the second connection part being located on the pair of first electrode regions.

### Configuration 2

The device according to configuration 1, wherein
a shape of the third electrode in the plane parallel to the second and third directions is a second hexagon,
the second hexagon includes:
   a pair of fourth sides parallel to each other, the pair of fourth sides being along the pair of first sides;
   a pair of fifth sides parallel to each other, the pair of fifth sides being along the pair of second sides; and
   a pair of sixth sides parallel to each other, the pair of sixth sides being along the pair of third sides,
a length of the pair of fourth sides being greater than a length of the pair of fifth sides.

### Configuration 3

A semiconductor device, comprising:
a first electrode;
a first semiconductor region located on the first electrode, the first semiconductor region being of a first conductivity type;
a second semiconductor region located on the first semiconductor region, the second semiconductor region being of a second conductivity type;
a third semiconductor region located on the second semiconductor region, the third semiconductor region being of the first conductivity type;
a second electrode located on the third semiconductor region, the second electrode being electrically connected with the third semiconductor region;
a structure body including
   an insulating part arranged with the third semiconductor region, the second semiconductor region, and a portion of the first semiconductor region in a second direction and a third direction, the second direction being perpendicular to a first direction, the first direction being from the first electrode toward the second electrode, the third direction being perpendicular to the first and second directions,
   a third electrode arranged with the first semiconductor region in the second and third directions with the insulating part interposed, and
   a fourth electrode surrounding the third electrode in the second and third directions, the fourth electrode being arranged with the second semiconductor region in the second and third directions with the insulating part interposed,
a first connection part located on the third electrode, the first connection part being electrically connected with the third electrode; and
a second connection part located on the fourth electrode, the second connection part being electrically connected with the fourth electrode,
a shape of the structure body in a plane parallel to the second and third directions being a first oval,
the first oval including
   a pair of first sides parallel to each other, and
   a pair of first arcs connecting the pair of first sides to each other,
the fourth electrode including
   a pair of first electrode regions along the pair of first sides, and
   a pair of second electrode regions along the pair of first arcs,
the second connection part being located on the pair of first electrode regions.

### Configuration 4

The device according to configuration 3, wherein
a shape of the third electrode in the plane parallel to the second and third directions is a second oval, and
the second oval includes:
   a pair of second sides parallel to each other, the pair of second sides being along the pair of first sides; and
   a pair of second arcs along the pair of first arcs, the pair of second arcs connecting the pair of second sides to each other.

### Configuration 5

The device according to any one of configurations 1 to 4, wherein
the pair of first sides is along the second direction, and
a length in the second direction of the second connection part is greater than a length in the third direction of the second connection part.

### Configuration 6

The device according to any one of configurations 1 to 5, wherein
the pair of first sides is along the second direction, and
a length in the second direction of the first connection part is greater than a length in the third direction of the first connection part.

### Configuration 7

The device according to any one of configurations 1 to 6, wherein
the first semiconductor region includes silicon, and
the pair of first sides is along a (100) plane of a crystal of the silicon included in the first semiconductor region.

Thus, according to embodiments, a semiconductor device can be provided in which the yield can be increased.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

What is claimed is:

1. A semiconductor device, comprising:
a first electrode;
a first semiconductor region located on the first electrode, the first semiconductor region being of a first conductivity type;
a second semiconductor region located on the first semiconductor region, the second semiconductor region being of a second conductivity type;
a third semiconductor region located on the second semiconductor region, the third semiconductor region being of the first conductivity type;
a second electrode located on the third semiconductor region, the second electrode being electrically connected with the third semiconductor region;
a structure body including
an insulating part arranged with the third semiconductor region, the second semiconductor region, and a portion of the first semiconductor region in a second direction and a third direction, the second direction being perpendicular to a first direction, the first direction being from the first electrode toward the second electrode, the third direction being perpendicular to the first and second directions,
a third electrode arranged with the first semiconductor region in the second and third directions with the insulating part interposed, and
a fourth electrode surrounding the third electrode in the second and third directions, the fourth electrode being arranged with the second semiconductor region in the second and third directions with the insulating part interposed,
a first connection part located on the third electrode, the first connection part being electrically connected with the third electrode; and
a second connection part located on the fourth electrode, the second connection part being electrically connected with the fourth electrode,
a shape of the structure body in a plane parallel to the second and third directions being a first hexagon,
the first hexagon including
a pair of first sides parallel to each other,
a pair of second sides parallel to each other, the pair of second sides crossing the pair of first sides, and
a pair of third sides parallel to each other, the pair of third sides crossing the pair of first sides and the pair of second sides,
a length of the pair of first sides being greater than a length of the pair of second sides,
the fourth electrode including
a pair of first electrode regions along the pair of first sides,
a pair of second electrode regions along the pair of second sides, and
a pair of third electrode regions along the pair of third sides,
the second connection part being located on the pair of first electrode regions.

2. The device according to claim 1, wherein
a shape of the third electrode in the plane parallel to the second and third directions is a second hexagon,
the second hexagon includes:
a pair of fourth sides parallel to each other, the pair of fourth sides being along the pair of first sides;
a pair of fifth sides parallel to each other, the pair of fifth sides being along the pair of second sides; and
a pair of sixth sides parallel to each other, the pair of sixth sides being along the pair of third sides,
a length of the pair of fourth sides being greater than a length of the pair of fifth sides.

3. The device according to claim 1, wherein
the pair of first sides is along the second direction, and
a length in the second direction of the second connection part is greater than a length in the third direction of the second connection part.

4. The device according to claim 1, wherein
the pair of first sides is along the second direction, and
a length in the second direction of the first connection part is greater than a length in the third direction of the first connection part.

5. The device according to claim 1, wherein
the first semiconductor region includes silicon, and
the pair of first sides is along a (100) plane of a crystal of the silicon included in the first semiconductor region.

6. A semiconductor device, comprising:
a first electrode;
a first semiconductor region located on the first electrode, the first semiconductor region being of a first conductivity type;
a second semiconductor region located on the first semiconductor region, the second semiconductor region being of a second conductivity type;
a third semiconductor region located on the second semiconductor region, the third semiconductor region being of the first conductivity type;
a second electrode located on the third semiconductor region, the second electrode being electrically connected with the third semiconductor region;
a structure body including
an insulating part arranged with the third semiconductor region, the second semiconductor region, and a portion of the first semiconductor region in a second direction and a third direction, the second direction being perpendicular to a first direction, the first direction being from the first electrode toward the second electrode, the third direction being perpendicular to the first and second directions,
a third electrode arranged with the first semiconductor region in the second and third directions with the insulating part interposed, and
a fourth electrode surrounding the third electrode in the second and third directions, the fourth electrode being arranged with the second semiconductor region in the second and third directions with the insulating part interposed,
a first connection part located on the third electrode, the first connection part being electrically connected with the third electrode; and
a second connection part located on the fourth electrode, the second connection part being electrically connected with the fourth electrode,
a shape of the structure body in a plane parallel to the second and third directions being a first oval,
the first oval including
a pair of first sides parallel to each other, and
a pair of first arcs connecting the pair of first sides to each other,
the fourth electrode including
a pair of first electrode regions along the pair of first sides, and
a pair of second electrode regions along the pair of first arcs,
the second connection part being located on the pair of first electrode regions.

7. The device according to claim 6, wherein
a shape of the third electrode in the plane parallel to the second and third directions is a second oval, and
the second oval includes:
a pair of second sides parallel to each other, the pair of second sides being along the pair of first sides; and
a pair of second arcs along the pair of first arcs, the pair of second arcs connecting the pair of second sides to each other.

8. The device according to claim 6, wherein
the pair of first sides is along the second direction, and
a length in the second direction of the second connection part is greater than a length in the third direction of the second connection part.

9. The device according to claim 6, wherein
the pair of first sides is along the second direction, and
a length in the second direction of the first connection part is greater than a length in the third direction of the first connection part.

10. The device according to claim 6, wherein
the first semiconductor region includes silicon, and
the pair of first sides is along a (100) plane of a crystal of the silicon included in the first semiconductor region.
